(19) United States
(12) Patent Application Publication
(10) Pub. No.: US 2007/0252268 A1
(43) Pub. Date: Nov. 1, 2007

(54) Thermally controllable substrate

(76) Inventors: Tong Fatt Chew, Penang (MY); Siew It Pang, Penang (MY); Sundar N. Yoganandan, Penang (MY); Yew Cheong Kuan, Penang (MY); Thye Linn Mok, Penang (MY)

Correspondence Address: Kathy Manke;Avago Technologies Limited, 4380 Ziegler Road, Fort Collins, CO, 80525, US

(21) Appl. No.: 11/395,303

(22) Filed: Mar. 31, 2006

(51) Int. Cl. H01L 23/34

(52) U.S. Cl. 257/714

(57) ABSTRACT

A thermally controllable substrate is disclosed. The substrate supports a heat generating source. One of more microchannels are embedded within the substrate and preferably circulate a cooling fluid to dissipate heat being generated by the source. The flow of the cooling fluid serves to remove heat entering the substrate proximate the source providing for the use of enhanced electrical devices which generate more heat in their normal operation.

### TECHNICAL FIELD

The present invention relates to a substrate for supporting a heat generating source. More particularly, the present invention relates to a substrate for supporting a heat generating source capable of dissipating heat away from the source.

### BACKGROUND OF THE INVENTION

Computer components can generate substantial heat which needs to be dissipated. For example, light-emitting diodes (LED), frequently used as light sources, generate a fair amount of heat. It is preferable to dissipate such heat to improve the operability and longevity of the heat source. Currently, the preferred way to achieve this is through the use of a substrate which incorporates a heat sink. Usually the heat sink is a mechanical radiator having a plurality of fins. The heat generated by the LED dissipates through the substrate and into the fins. In this matter, the heat is dissipated.

A disadvantage of such a design is that the heat removal rate is relatively low. Additionally, the overall profile of the LED, substrate, and heat sink is relatively thick which limits its usefulness in certain applications where the dimension of the LED assembly is critical. Furthermore, the use of a plurality of such LED assemblies having a passive heat sink can increase the overall weight of the unit.

As electrical components, such as an LED, improve in overall design and assume more significant operational requirements, the amount of heat generated by such units increases. This is also the case for other types of heat-generating computer components such as microprocessors. Therefore, the need exists for an improved substrate which can dissipate heat faster allowing such electrical devices to operate at faster rates and generate more heat.

### BRIEF SUMMARY OF THE INVENTION

The present invention is a thermally controllable substrate for a heat-generating source, such as an LED, which includes an electrically conductive base having a longitudinal axis. At least one channel is formed within the base that is capable of conducting a cooling fluid.

In the manufacture of such a substrate, an electrically conductive layer is provided having a first and second side. A strip is created along the first side of the layer. A second electrically conductive layer is attached to the first side of the first layer defining at least one enclosed channel capable of conducting a cooling fluid.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 is a cross-sectional view of a portion of a substrate, according to embodiments of the present invention;

FIG. 2 is a cross-sectional view of an alternate arrangement of a portion of a substrate, according to embodiments of the present invention;

FIG. 3 is an unassembled top view of a substrate, according to embodiments of the present invention;

FIG. 4 is an assembled top view of a substrate, according to embodiments of the present invention;

FIG. 5 is an elevation view of yet another alternate arrangement of a substrate, according to embodiments of the present invention;

FIG. 6 is a perspective view of the alternate arrangement shown in FIG. 5.

### DETAILED DESCRIPTION OF THE INVENTION

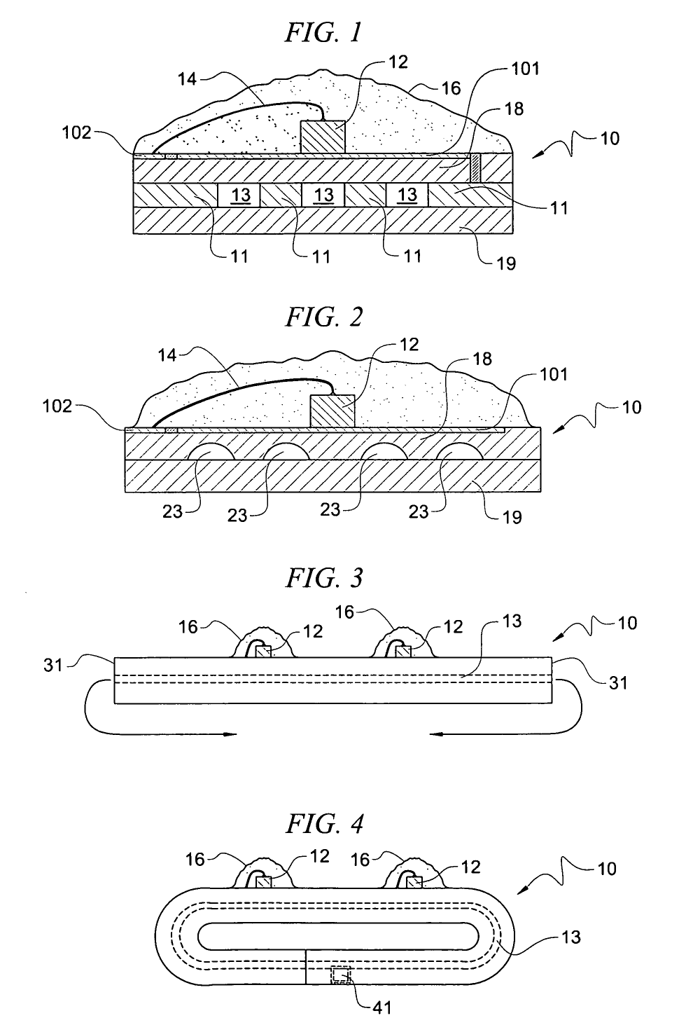

Referring to FIG. 1, substrate 10 supports a heat generating source or electrical device, such as an LED chip 12. Substrate 10 may support any type of heat generating device, such as a microprocessor, which generates heat during operation and, for optimal operational capability and reliability, requires the dissipation of that heat. Referring still to FIG. 1, LED chip 12 is electrically connected by a bond wire 14 to an electrical circuit. In this manner, light, and in turn heat, emanates from LED chip 12. LED chip 12 may be encapsulated by a compliant and transparent material 16 for reliability and protectability. Substrate 10 is shown as comprising cathode pad 101, anode pad 102, layer 18 and layer 19. Layers 18 and 19 are electrically conductive in whole or in part. Layer 18 is attached to pads 101 and 102. Spaced intermediately between 18 and 19 are conductive spacers 11 which are attached, or at a minimum electrically connected, to the inside surfaces of layers 18 and 19. In this manner, one or more open channels 13 are formed. Occasionally, channels 13 may be referred to as microchannels.

In this manner, heat generated by LED chip 12 or other heat generating electrical device emanates through layer 18 and into microchannels 13. A cooling fluid, such as a liquid, is circulated through channels 13 permitting transfer of the heat away from that portion of layer 19 and spacers 11 proximate LED chip 12. Thus, substrate 10 acts as a heat dissipater transferring heat away from LED chip 12 through the circulation of the cooling fluid within microchannels 13.

Referring to FIG. 2, one or more microchannels 23 may be created by etching each microchannel on the inside surface of layer 18. In this manner, separate spacers 11 are not required. Once layers 18 and 19 are attached, a cooling fluid is permitted to circulate within microchannels 23. Etched microchannels 23 may be formed on layer 19 rather than layer 18, or a combination of both.

Referring to FIGS. 3 and 4, substrate 10 is shown during the assembly phase. Preferably, substrate 10 is manufactured of a flexible and pliable material, which is easily bendable into a final shape. As show in FIG. 3, substrate 10 may include one or more heat generating devices or sources such as LED chips 12. Microchannels 13 pass through substrate 10, preferably substantially parallel with the longitudinal axis of substrate 10. During the manufacturing phase, substrate 10 may be bent and joined at its ends 31 as shown in FIG. 4. During the joining phase, the open ends of each microchannel are aligned to ensure fluid conductivity once ends 31 are joined. Thus, the cooling fluid may circulate through microchannels 13 in a loop fashion dissipating heat.

Referring still to FIG. 4, an embodiment of the present invention may include a microelectrical mechanical system (MEMS) pump or similar device 41, which is housed near or adjacent to one or more of microchannels 13. A commercially available MEM pump 41 may be used to circulate the cooling fluid within each microchannel 13. The circulating fluid within microchannel 13 withdraws the heat from that portion of substrate 10 proximate LED chip 12. The heat within the fluid is then transferred to cooler portions of the substrate which serve to remove the heat and allow the fluid circulating within microchannels 13 to cool. Thus, the fluid circulating within microchannels 13 act as a fluid dissipating the heat and permitting the use of enhanced electrical devices such as faster microprocessors and brighter LEDs that improve the operability of the overall electrical system.

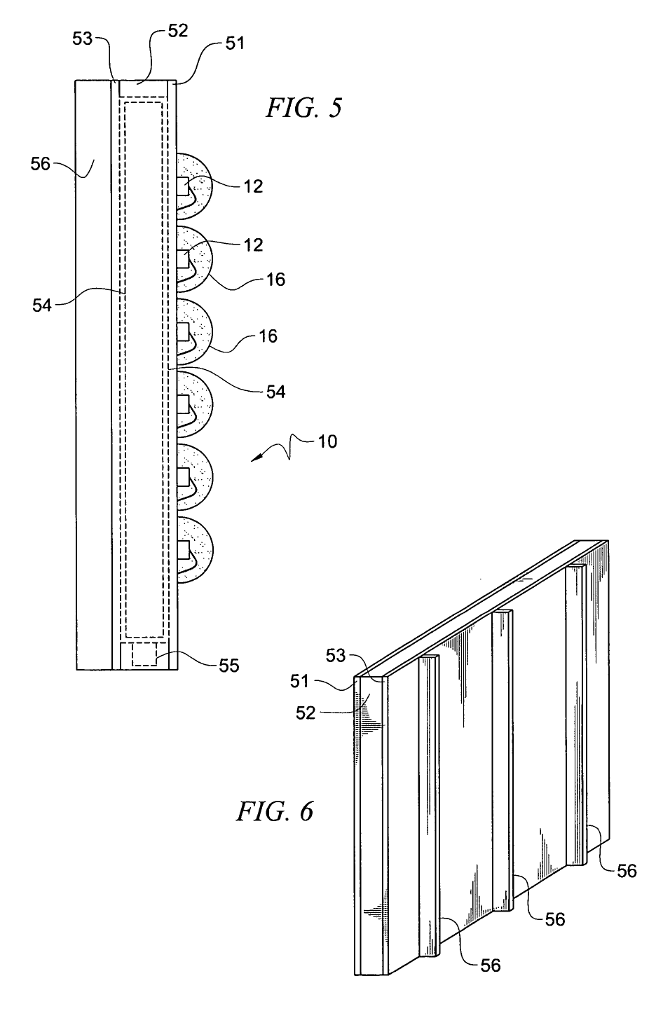

Referring now to FIG. 5, yet another alternate embodiment of the present invention is shown. Rather than using a relatively flexible and pliable substrate 10 as shown in FIGS. 3 and 4, substrate 10 of FIG. 5 comprises a relatively inflexible material such as aluminum or other metallic or metallic alloy materials. A heat-generating device, such as LED chips 12, is shown attached to layer 51. One or more microchannels 54 are machined or etched between layers 51, 52 and 53 so that when layers 51, 52 and 53 are joined a fully enclosed microchannel 54 is created. A cooling fluid is permitted to circulate within microchannel 54 thereby dissipating the heat being generated by LED chips 12. A MEM pump 55 may be located proximate microchannel 54. As discussed above, MEM pump 55 would be used to circulate the cooling fluid within microchannel 54 dissipating the heat being generated by each heat generating device.

Referring now to FIG. 6, either the flexible substrate embodiment shown in FIGS. 3 and 4 or the more inflexible substrate embodiment shown in FIG. 5 may include auxiliary cooling systems. In FIG. 6, such an auxiliary cooling system is shown as auxiliary fins 56 preferably mounted perpendicular to the planer surface of layer 53. Fins 56 are also shown in FIG. 5. In this manner, fins 56 serve to accelerate the dissipation of heat through the substrate 10 as the cooling fluid circulating within microchannel 54 dissipates heat away from the heat generating devices. In substitution of, or in addition to, fins 56, the surface of layers 51, 52 and 53 may include a rough textured surface to further enhance the heat dissipating characteristics of substrate 10.

In any of the embodiments shown in FIGS. 1-7, microchannels 13/23/54 may be oriented to take advantage of gravitational forces. That is, the microchannels may be oriented to permit the hotter fluid circulating in each microchannel to rise distal the heat generating device thereby encouraging the cooler fluid circulating within the microchannel to sink and advance toward the heat generating device. This effect may be coupled with the circulatory flow provided by MEM pump 41/53 accelerates the dissipation of heat.

It will be apparent to those skilled-in-the-art that the number of microchannels 13/23/54 can be modified to accommodate the particular heat generating properties of each electrical device. It may be beneficial, for example, to have a single large microchannel rather than several smaller microchannels with a larger MEMS pump operating through one channel to improve heat dissipation. Each microchannel 13/23/54 is filled with the cooling fluid through a pilot hole (not shown) which is sealed following filling.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A thermally controllable substrate for a heat-generating source comprising:
an electrically conductive base that receives a portion of the heat from the source; and
at least one channel formed within said base that conducts a cooling fluid.

2. The substrate according to claim 1 wherein said base comprises:
a flexible material, and
said at least one channel extends substantially parallel to a longitudinal axis of said base so that said base may be bent and the opposite ends of said base joined aligning said at least one channel in fluid communication.

3. The substrate according to claim 1 wherein said substrate includes a cooling fluid within said at least one channel.

4. The substrate according to claim 1 wherein said base comprises at least two substantially parallel channels.

5. The substrate according to claim 1 wherein said base comprises at least three substantially parallel channels.

6. The substrate according to claim 1 wherein said base comprises a relatively inflexible material.

7. The substrate according to claim 6 wherein said at least one channel comprises a closed loop within said base and oriented generally perpendicular to a longitudinal axis of said base.

8. The substrate according to claim 6 wherein said substrate further includes means for auxiliary cooling of the substrate.

9. The substrate according to claim 9 wherein said auxiliary cooling means comprises a plurality of fins mounted to one surface of said base.

10. The substrate according to claim 6 wherein said substrate further includes means for circulating said cooling fluid within said at least one channel.

11. A substrate supporting a heat-generating electrical component comprising:
a flexible electrically conductive base that receives a portion of the heat from the component; and
at least one channel formed within said base extending substantially parallel to the longitudinal axis of said base and capable of conducting a cooling fluid,
wherein said base may be bent and the opposite ends of said base joined aligning at least one channel in fluid communication.

12. The substrate according to claim 11 wherein said substrate includes a cooling fluid within said at least one channel.

13. The substrate according to claim 11 wherein said base comprises at least two substantially parallel channels.

14. The substrate according to claim 11 wherein said base comprises at least three substantially parallel channels.

15. The substrate according to claim 11 wherein said substrate further includes means for circulating said cooling fluid within said at least one channel.

16. A thermally controllable substrate for a light emitting diode comprising:
an electrically conductive base that receives heat from the diode; and
at least one channel formed within said base capable of conducting a cooling fluid.

17. The substrate according to claim 16 wherein said base comprises:
a flexible material, and
said at least one channel extends substantially parallel to a longitudinal axis of said base so that said base may be bent and the opposite ends of said base joined aligning said at least one channel in fluid communication.

18. The substrate according to claim 16 wherein said substrate includes a cooling fluid within said at least one channel.

19. A substrate supporting a light emitting diode comprising:
a flexible electrically conductive base; and
at least one channel formed within said base extending substantially parallel to the longitudinal axis of said base and capable of conducting a cooling fluid,
wherein said base may be bent and the opposite ends of said base joined aligning at least one channel in fluid communication.

20. The substrate according to claim 19 wherein said substrate includes a cooling fluid within said at least one channel.

21. The substrate according to claim 19 wherein said substrate further includes means for circulating said cooling fluid within said at least one channel.

22. A method for manufacturing a substrate supporting a heat-generating electrical device, comprising the steps of:
providing a first electrically conductive layer having a first and second side;
creating at least one strip along the first side of said first layer; and
attaching a second electrically conductive layer to said first side of said first layer defining at least one enclosed channel capable of conducting a fluid.

23. The method according to claim 22 wherein said first and second layers comprise a flexible material, the method further comprising the steps of:
bending said first and second layers;
filling said at least one channel with a fluid; and
attaching the ends of said first and second layers so as to align the ends of said at least one channel enabling the fluid within said at least one channel to remain in fluid communication throughout.

24. A method for manufacturing a substrate, comprising the steps of:
providing an electrical device source electrically connected to a first conductive layer having a first and second side;
attaching at least two substantially parallel intermittently spaced electrical conductive spacers to said first side of said first conductive layer; and
attaching a second conductive layer to said spacers defining at least one channel between said at least two spacers and said first and second conductive layers.

25. The method according to claim 24, wherein said first and second layers and said spacers comprise a flexible material, the method further comprising the steps of:
bending said first and second layers and said spacers;
filling said at least one channel with a fluid; and
connecting the ends of said first and second layers so as to align the ends of said at least one channel enabling said fluid to remain within said channel in fluid communication.
